(19) United States
(12) Patent Application Publication
(10) Pub. No.: US 2021/0187685 A1
(43) Pub. Date: Jun. 24, 2021

(54) SUBSTRATE PROCESSING APPARATUS, SUBSTRATE PROCESSING METHOD, AND SUBSTRATE PROCESSING SYSTEM

(71) Applicant: EBARA CORPORATION, Tokyo (JP)

(72) Inventors: Atsuo Katagiri, Tokyo (JP); Itsuki Kobata, Tokyo (JP)

(21) Appl. No.: 17/132,573

(22) Filed: Dec. 23, 2020

(30) Foreign Application Priority Data
Dec. 24, 2019 (JP) 2019-232847
Dec. 24, 2019 (JP) 2019-232849

(51) Int. Cl. B24B 1/00; H01L 21/306; H01L 21/67; H01L 21/3105; H01L 21/321

(52) U.S. Cl. CPC B24B 1/002; H01L 21/30625; H01L 21/67219; H01L 21/30635; H01L 21/3212; H01L 21/32125; H01L 21/31053

(57) ABSTRACT

A substrate processing apparatus comprising: a stage for holding a substrate with a surface to be processed upward; a catalyst holding head for holding a catalyst to process the surface to be processed of the substrate; a pushing mechanism for pushing the catalyst holding head against the surface to be processed of the substrate; a swing mechanism for swinging the catalyst holding head in a radial direction of the substrate; and a pushing force control unit configured to adjust a pushing force of the catalyst holding head by the pushing mechanism according to a position of the catalyst holding head or a contact area between the substrate and the catalyst when the catalyst projects to outside the substrate by the swing of the catalyst holding head.

### TECHNICAL FIELD

This application relates to a substrate processing apparatus, a substrate processing method, and a substrate processing system. This application claims priority from Japanese Patent Application No. 2019-232847 filed on Dec. 24, 2019, and Japanese Patent Application No. 2019-232849 filed on Dec. 24, 2019. The entire disclosure including the descriptions, the claims, the drawings, and the abstracts in Japanese Patent Application No. 2019-232847 and Japanese Patent Application No. 2019-232849 is herein incorporated by reference.

### BACKGROUND ART

In manufacturing processes of semiconductor devices, a chemical mechanical polishing (CMP) has been widely used for processing a surface of a substrate. A CMP apparatus polishes the surface of the substrate by having a polishing head hold the substrate as a process target, pushing the substrate on a polishing pad installed on a polishing table, and causing the polishing head and the polishing table to make relative movement while supplying a slurry between the polishing pad and the substrate.

In association with miniaturization of current semiconductor device structures, a planarization technique with higher accuracy, a processing accuracy in an angstrom order, and a processing technique without any damage have been demanded. The planarization process typified by the CMP is no exception. While a removal amount itself decreases to, for example, around 100 Å, in association with the miniaturization, controllability at an atomic level is required. In order to satisfy this requirement, conditions of polishing and cleaning are optimized in the CMP. However, since the CMP polishes the surface of the substrate using abrasive grains, mechanical damages are likely to be generated on the substrate, and processing without any damage is difficult. Therefore, a catalyst referred etching (CARE) is proposed as a new processing technique. With the CARE technique, a catalyst and a process target are brought into contact in a process liquid with the catalyst defined as a reference surface. As a result, reactive species generated on the surface of the catalyst and the process target substrate cause chemical reaction, and thus, materials of the surface of the substrate are removed. The catalyst referred etching (CARE) as described in PTL 1 is proposed as the new processing technique. The CARE method generates reactive species with a surface to be processed in a process liquid only near a catalyst material in the presence of the process liquid and causes the catalyst material to be adjacent to or contact the surface to be processed to ensure selectively causing an etching reaction of the surface to be processed in the surface adjacent to or in contact with the catalyst material. For example, on the surface to be processed having unevenness, causing a projecting portion to be adjacent to or contact the catalyst material allows selective etching of the projecting portion, thus ensuring planarization of the surface to be processed.

A substrate processing apparatus employing the CARE technique includes a stage that holds a substrate with a surface to be processed upward and a catalyst holding head that holds a catalyst to process the surface to be processed of the substrate. The substrate processing apparatus supplies a process liquid to the substrate, pushes the catalyst holding head against the surface to be processed of the substrate, and swings the catalyst holding head in a radial direction of the substrate to bring the catalyst into contact with the substrate in the process liquid. Consequently, reactive species generated on a catalyst surface and the substrate cause a chemical reaction, thus removing a material of the substrate surface.

### CITATION LIST

### Patent Literature

PTL 1: WO 2015-159973

PTL 2: Japanese Unexamined Patent Application Publication No. 2008-121099

### SUMMARY OF INVENTION

### Technical Problem

To uniformly process the whole surface of the surface to be processed of the substrate by the CARE reaction, a distribution of a contact period between the catalyst and the surface to be processed of the substrate needs to be uniform. Here, it is disclosed that, in the substrate processing apparatus described in PTL 1, since the catalyst has a size smaller than that of the substrate, to ensure the contact period especially at a substrate outer peripheral portion, the catalyst holding head is swung (overhung) until projecting to outside the substrate.

However, when a constant load is applied to the catalyst holding head in the planarization process in CARE, since a contact area between the catalyst and the surface to be processed of the substrate decreases during the overhang, an excessive contact load is applied to a portion of the catalyst holding head not projecting from the substrate. This generates an excessive scratch between the outer peripheral portion of the substrate and the catalyst, and this causes abrasion of the catalyst and peeling of the catalyst from the catalyst holding head. As a result, the substrate itself may be defaced, or the surface to be processed of the substrate may be damaged. Since the defacement and the damage directly affect performance of a device, reduction in them required.

Therefore, one object of this application is to suppress damage to a substrate and damage to a surface to be processed caused by overhang of a catalyst holding head in a substrate processing apparatus employing a CARE technique.

For application of the CARE method to a planarization process of the substrate, uniformly removing two or more kinds of semiconductor materials is required in some cases. The target semiconductor materials include a Low-k material as an oxidized film as an insulating film, W and Cu as a wiring material, and a metallic material as a barrier metal, such as TaN and TiN, and further in the next-generation. Examples of the materials include a novel material, such as ruthenium (Ru) and cobalt (Co), and highly accurate planarization on heterogeneous layers containing these materials is desired. However, in a situation in which these materials mix, since etching characteristics of the respective materials differ, planarization by a single CARE process is difficult. Accordingly, a CARE process according to a kind and a state of an exposed material is required.

Therefore, in view of the above-described problems, one object of this disclosure is to provide a substrate processing apparatus that allows planarization of different materials in a process by CARE.

### Solution to Problem

According to one embodiment, there is disclosed a substrate processing apparatus that includes a stage, a catalyst holding head, a pushing mechanism, a swing mechanism, and a pushing force control unit. The stage holds a substrate with a surface to be processed upward. The catalyst holding head holds a catalyst to process the surface to be processed of the substrate. The pushing mechanism pushes the catalyst holding head against the surface to be processed of the substrate. The swing mechanism swings the catalyst holding head in a radial direction of the substrate. The pushing force control unit is configured to adjust a pushing force of the catalyst holding head by the pushing mechanism according to a position of the catalyst holding head or a change in a contact area between the substrate and the catalyst when the catalyst projects to outside the substrate by the swing of the catalyst holding head.

According to one embodiment, there is provided a substrate processing apparatus. In a substrate as a process target, an insulating film layer in which a groove is formed, a barrier metal layer, and a wiring metal layer are formed in an order from a lower side in at least a part of a region. The substrate processing apparatus includes a table that holds the substrate and a head that holds a catalyst. The catalyst contains a base metal.

### BRIEF DESCRIPTION OF DRAWINGS

FIG. 1 is a schematic plan view illustrating a schematic configuration of a substrate processing apparatus as one embodiment of the present invention;

FIG. 2 is a side view of the substrate processing apparatus illustrated in FIG. 1;

FIG. 3A and FIG. 3B are schematic cross-sectional views illustrating details of a catalyst holding head;

FIG. 4 is a schematic cross-sectional side view illustrating a catalyst holding head 30 in a state mounted to a swing arm as one embodiment;

FIG. 5 is a schematic diagram illustrating a configuration to control a force of pushing the catalyst holding head 30 to a surface to be processed of a wafer W using the swing arm as one embodiment;

FIG. 6 is a flowchart depicting a flow of performing PID control on a contact pressure between the catalyst holding head and the wafer W as one embodiment;

FIG. 7 is a drawing schematically illustrating a state of overhanging the catalyst holding head from the wafer;

FIG. 8 is a graph showing a ratio of a contact area between the wafer and a catalyst and a ratio of the pushing force of the catalyst holding head to a position of the catalyst holding head;

FIG. 9 is a flowchart depicting a substrate processing method by the substrate processing apparatus;

FIG. 10 is a plan view illustrating a schematic configuration of a substrate processing system as one embodiment;

FIG. 11 is a schematic plan view of the substrate processing apparatus according to one embodiment;

FIG. 12 is a side view of the substrate processing apparatus illustrated in FIG. 11;

FIG. 13 is a graph showing results of a catalyst referred etching using various kinds of single metallic catalysts using a substrate including a ruthenium (Ru) layer on its surface;

FIG. 14 is a graph showing results of the catalyst referred etching using various kinds of single metallic catalysts using the substrate including the ruthenium (Ru) layer on its surface;

FIG. 15 is a graph showing results of a catalyst referred etching using various kinds of single metallic catalysts using a substrate including a cobalt (Co) layer on its surface;

FIG. 16 is a graph showing results of a catalyst referred etching using various kinds of single metallic catalysts using the substrate including the cobalt (Co) layer on its surface;

FIG. 17 is a graph showing results of a catalyst referred etching using various kinds of single metallic catalysts using a substrate including a TiN layer on its surface;

FIG. 18 is a graph showing results of a catalyst referred etching using various kinds of single metallic catalysts using the substrate including the TiN layer on its surface;

FIG. 19 is a graph showing results of a catalyst referred etching using various kinds of single metallic catalysts using the substrate including the TiN layer on its surface;

FIG. 20 is a graph showing results of a catalyst referred etching using various kinds of single metallic catalysts using a substrate including a TEOS layer on its surface;

FIG. 21 is a graph showing results of a catalyst referred etching using various kinds of single metallic catalysts using the substrate including the TEOS layer on its surface;

FIG. 22 is a graph showing results of a catalyst referred etching in which component concentrations in process liquids were changed in the respective layers of Ru, TiN, and TEOS;

FIG. 23 is a graph that compares removal rates when a CARE process was performed with respective catalysts on the respective layers of Ru, TiN, and TEOS;

FIG. 24 is a graph that compares removal rates when a CARE process was performed with respective catalysts on the respective layers of Co, TiN, and TEOS; and

FIG. 25 is a block diagram schematically illustrating a substrate processing system according to one embodiment.

### DESCRIPTION OF EMBODIMENTS

The following describes embodiments of a substrate processing apparatus and a substrate processing method according to the present invention with reference to the attached drawings. In the attached drawings, identical or similar reference numerals are attached to identical or similar components, and overlapping description regarding the identical or similar components may be omitted in the description of the respective embodiments. Features illustrated in the respective embodiments are applicable to other embodiments in so far as they are consistent with one another.

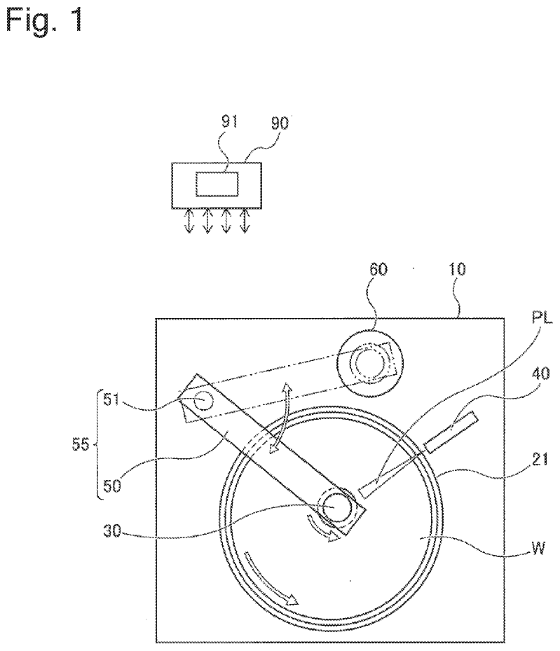

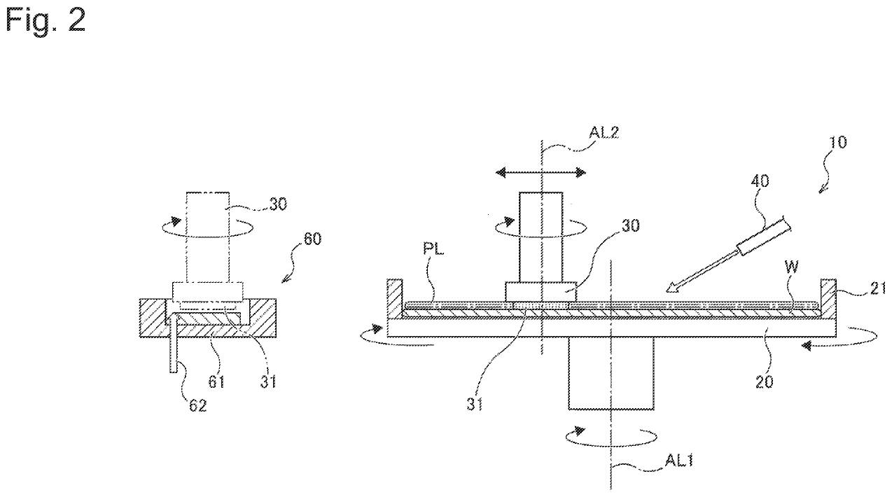

FIG. 1 is a schematic plan view illustrating a schematic configuration of a substrate processing apparatus 10 as one embodiment of the present invention. FIG. 2 is a side view of the substrate processing apparatus 10 illustrated in FIG. 1. The substrate processing apparatus 10 is an apparatus that performs an etching process on a semiconductor material (processed region) on a substrate using a CARE method.

The substrate processing apparatus 10 includes a stage 20, a catalyst holding head 30, a process liquid supply member 40, a swing arm 50, a conditioning member 60, and a control unit 90. The stage 20 holds a wafer W as one kind of the substrate. In this embodiment, the stage 20 holds the wafer W with a surface to be processed (polished surface) of the wafer W upward. In this embodiment, the stage 20 includes a vacuum suction mechanism that performs vacuum suction on a back surface (a surface on a side opposite to the polished surface) of the wafer W as a mechanism to hold the wafer W. As a method of the vacuum suction, both of a point suction method using a suction plate having a plurality of suction holes connected to a vacuum line in a suction surface, and a surface suction method that performs suction through a connecting hole, which is provided in a groove (for example, a concentric shape) in a suction surface, to a vacuum line may be used. Additionally, for stabilization of a suction state, a backing material may be pasted to the suction plate surface and the wafer W may be suctioned via this backing material.

The stage 20 is rotatable around an axis line AL1 by a rotation drive mechanism, such as a motor (not illustrated). In this drawing, the stage 20 includes a wall member 21 that extends vertically upward in the whole circumferential direction outside a region to hold the wafer W. This allows holding a process liquid inside the wafer surface, and as a result, usage of the process liquid can be reduced. While the wall member 21 is fixed to an outer periphery of the stage 20 in this drawing, the wall member 21 may be configured separately from the stage 20. In the case, the wall member 21 may vertically move. The wall member 21 configured to vertically move allows changing an amount of held process liquid, and, for example, when the substrate surface after the etching process is cleaned, lowering the wall member 21 allows efficiently discharging a cleaning liquid to outside the wafer W.

The catalyst holding head 30 of the embodiment illustrated in FIG. 1 and FIG. 2 has a lower end holding a catalyst 31. In this embodiment, the catalyst 31 is smaller than the wafer W. That is, a projection area of the catalyst 31 when projected from the catalyst 31 to the wafer W is smaller than an area of the wafer W. The catalyst holding head 30 is configured to be rotatable around an axis line AL2 by the rotation drive mechanism, such as the motor (not illustrated).

The process liquid supply member 40 supplies the surface of the wafer W with a process liquid PL. Here, while the process liquid supply member 40 is one in this drawing, a plurality of the process liquid supply members 40 may be disposed, and, for example, when a plurality of process target materials are mixed on the surface to be processed of the wafer W, a plurality of process liquids may be used for the individual materials. In the case, the different process liquids may be supplied from the respective process liquid supply members. Here, as the process liquid, for example, ozone water, acid, an alkaline solution, H₂O₂ water, a hydrofluoric acid solution, a combination of these substances, and the like can be used. When the wafer W surface is cleaned in the substrate processing apparatus 10 after the etching process, liquid medicine for cleaning and water may be supplied from the process liquid supply member 40. Additionally, the process liquid supply member 40 may be fixed to the swing arm 50 near the catalyst holding head 30, preferably at an upstream portion of a rotation of the wafer W, that is, a position where the rotation of the wafer W efficiently supplies the process liquid supplied from the process liquid supply member 40 to the catalyst holding head 30. In this case, the process liquid supply member 40 is configured to move together with the catalyst holding head 30. This configuration allows always supplying the fresh process liquid PL to the periphery of the catalyst 31, and as a result, etching performance is stabilized. Regardless of a configuration of a swing movement of the catalyst holding head 30 by the swing arm 50, the process liquid can be supplied to a neighborhood of a contact portion between the catalyst 31 and the wafer W, thereby ensuring reducing the usage of the process liquid.

The substrate processing apparatus 10 includes a swing mechanism 55 to swing catalyst holding head 30 in a radial direction of the wafer W. The swing mechanism 55 includes the swing arm 50, which holds the catalyst holding head 30, and a rotation shaft 51 that rotatably holds the swing arm 50. The swing arm 50 is configured to be swingable around the rotation shaft 51 and vertically movable by the rotation drive mechanism, such as the motor (not illustrated). The swing arm 50 has a distal end (an end portion on a side opposite to the rotation shaft 51) to which the catalyst holding head 30 is rotatably mounted. Here, since this CARE method generates etching only at the contact portion with the catalyst, a distribution of a contact period between the wafer W and the catalyst 31 in the wafer surface significantly affects a distribution of an amount of etching in the wafer surface. Regarding this point, making a swing rate of the swing arm 50 in the wafer surface variable allows uniforming the distribution of the contact period. Specifically, a swing range of the swing arm 50 in the wafer W surface is divided into a plurality of sections, and the swing rate is controlled in each section.

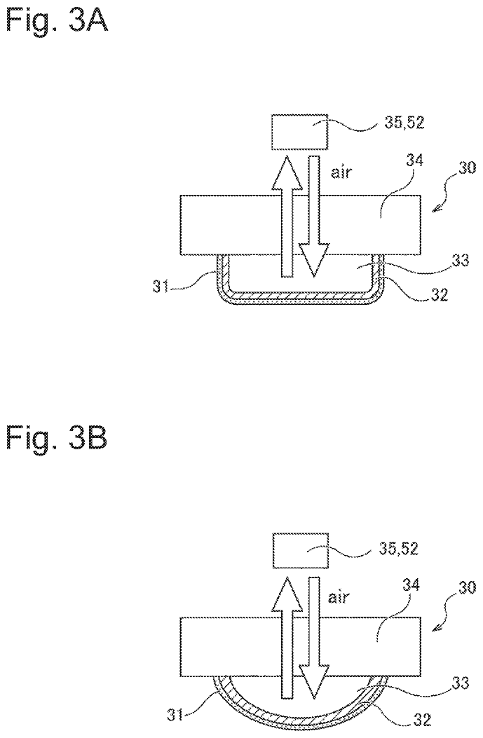

FIG. 3A and FIG. 3B are schematic cross-sectional views illustrating details of the catalyst holding head 30. As illustrated in FIG. 3A, the catalyst holding head 30 includes an elastic member 32 that holds the catalyst 31 and a base material 34 that holds the elastic member 32. The elastic member 32 is formed of an elastic film, and a pressure chamber 33 is formed between the elastic member (elastic film) 32 and the base material 34. A layer of the catalyst 31 is formed on an outer surface of the elastic member 32. In this embodiment, the catalyst 31 is deposited on the outer surface of the elastic member 32. Candidates for a material of the elastic member include nitrile rubber, hydrogenated nitrile rubber, fluoro-rubber, silicone rubber, ethylene propylene rubber, chloroprene rubber, acrylic rubber, butyl rubber, urethane rubber, isoprene rubber, styrene butadiene rubber, butadiene rubber, polyethylene rubbers, epichlorohydrin rubber, polytetrafluoroethylene, PolyTriFluoroChloroEthylene, perfluoroalkyl, fluorinated ethylene propylene, polycarbonate, polyethylene, vinyl chloride, polymethylmethacrylate, polypropylene, polyether ether ketone, polyimide, and the like. A film forming method of the catalyst 31 includes methods of physical vapor deposition, such as resistance heating vapor deposition and sputter deposition, and chemical vapor deposition, such as CVD. Additionally, the catalyst 31 may be formed by another film forming method, such as electrolytic plating and electroless plating.

The substrate processing apparatus 10 includes a fluid source 35 that supplies a fluid to a space (pressure chamber 33) formed between the base material 34 and the elastic member 32 as a pushing mechanism 52 that pushes the catalyst holding head 30 against the surface to be processed of the wafer W. The control unit 90 includes a pushing force control unit 91 that controls a force of pushing the catalyst holding head 30 against the surface to be processed of the wafer W. The pushing force control unit 91 controls a flow rate of the fluid (here, air, but may be a nitrogen gas or the like) supplied from the fluid source 35 to the pressure chamber 33 to control the pushing force of the catalyst 31 (catalyst holding head 30) to the processed region of the wafer W. This configuration deforms the elastic member 32 when the catalyst 31 is brought into contact with the processed region of the wafer W. and therefore the catalyst 31 can uniformly contact the wafer W following a shape of the wafer W (such as a warp of the wafer W). As a result, the etching rate at the contact portion between the catalyst 31 and the wafer W can be uniformed.

In this embodiment, as illustrated in FIG. 3A, the pressure chamber 33 has a substantially rectangular parallelepiped shape or columnar shape. Note that the pressure chamber 33 can have any shape. For example, as illustrated in FIG. 3B, the pressure chamber 33 may have an arc shape or a hemispherical shape. The pressure chambers 33 having these simple shapes allow further uniforming the contact state between the catalyst 31 and the wafer W.

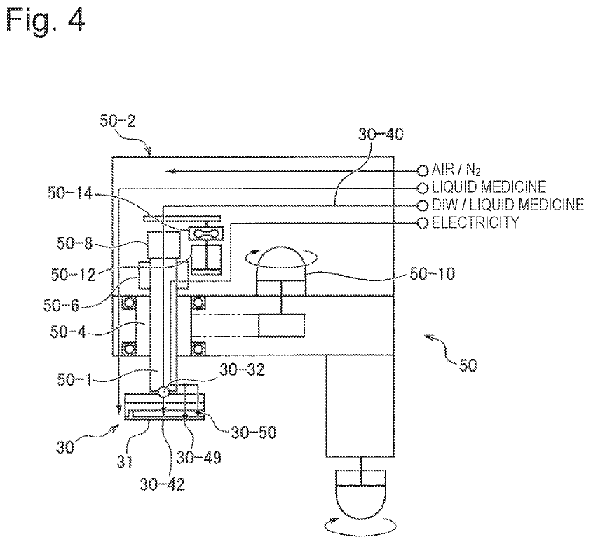

As one embodiment, the catalyst holding head 30 disclosed by this specification can be mounted to the swing arm 50. FIG. 4 is a schematic cross-sectional side view illustrating the catalyst holding head 30 in the state mounted to the swing arm 50 as one embodiment. As illustrated in FIG. 4, the whole swing arm 50 is surrounded by a cover 50-2. The catalyst holding head 30 is connected to a shaft 50-1 via a gimbal mechanism 30-32. The shaft 50-1 is rotatably supported by a ball spline 50-4, a slip ring 50-6, and a rotary joint 50-8. Note that, instead of the slip ring 50-6, a rotary connector may be used, or electrical connection may be contactlessly achieved.

The catalyst holding head 30 can be rotated by a rotation motor 50-10. The shaft 50-1 is axially driven by an elevating air cylinder 50-12. As the air cylinder 50-12, an air bearing cylinder can be used. The use of the air bearing cylinder allows reducing a sliding resistance and also reducing hysteresis. The air cylinder 50-12 is connected to the shaft 50-1 via a load cell 50-14, and the load cell 50-14 can measure a force provided from the air cylinder 50-12 to the shaft 50-1.

The swing arm 50 includes a process liquid supply passage 30-40 that can supply the process liquid and/or water from a supply port 30-42 in a surface of the catalyst 31 of the catalyst holding head 30. The process liquid and/or water may be supplied from the outside of the catalyst holding head 30. The swing arm 50 is configured to be connected to a supply source of air or nitrogen to supply the air or the nitrogen to the inside of the cover 50-2. There may be a case where the CARE process uses liquid medicine with high corrosivity, and therefore the inside of the cover 50-2 is set to be higher than an external pressure to ensure preventing an entrance of the process liquid PL into the cover 50-2.

A catalyst electrode 30-49 is disposed to be electrically connected to the catalyst 31. Meanwhile, a counter electrode 30-50 is disposed such that a voltage can be applied to the catalyst 31 via the process liquid PL. A voltage can be applied to the catalyst electrode 30-49 and the counter electrode 30-50 by an external power source. The CARE method allows adjusting the etching rate through the application of a voltage between the catalyst electrode 30-49 and the counter electrode 30-50.

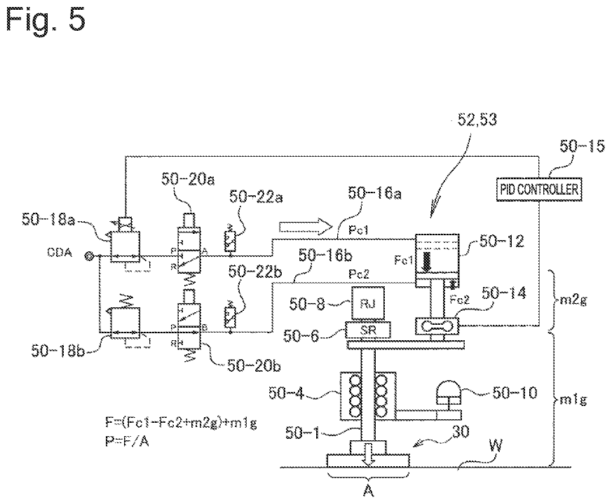

FIG. 5 is a schematic diagram illustrating a configuration to control the force of pushing the catalyst holding head 30 against the surface to be processed of the wafer W using the swing arm 50 as one embodiment. As illustrated in FIG. 5, the substrate processing apparatus 10 includes the pushing mechanism 52 that pushes the catalyst holding head 30 against the surface to be processed of the wafer W. In the embodiment of FIG. 5, the pushing mechanism 52 includes an elevating mechanism 53 that moves up and down the catalyst holding head 30. The elevating mechanism 53 specifically includes the air cylinder 50-12, an electropneumatic regulator 50-18a, a precise regulator 50-18b, a PID controller 50-15, and the like.

A first pipe line 50-16a to supply air is connected to one side of a piston of the air cylinder 50-12. To the first pipe line 50-16a, the electropneumatic regulator 50-18a, a solenoid valve 50-20a, and a pressure gauge 50-22a are connected. The electropneumatic regulator 50-18a is connected to the PID controller 50-15 and converts an electrical signal received from the PID controller 50-15 into an air pressure. The solenoid valve 50-20a is a normally closed valve and flows the air during ON. The pressure gauge 50-22a can measure a pressure inside the first pipe line 50-16a. To the other side of the piston of the air cylinder 50-12, a second pipe line 50-16b to supply the air is connected. To the second pipe line 50-16b, the precise regulator 50-18b, a solenoid valve 50-20b, and a pressure gauge 50-22b are connected. The solenoid valve 50-20b is a normally open valve and flows the air during OFF. The pressure gauge 50-22b can measure a pressure inside the second pipe line 50-16b. An air pressure to cancel own weight m2g+m1g from the air cylinder 50-12 to the catalyst holding head 30 is provided to the second pipe line 50-16b. Note that m2g is a load above the load cell 50-14 and included in the measurement by the load cell 50-14, and m1g is a load under the load cell 50-14 and not included in the measurement by the load cell 50-14. As described above, the load cell 50-14 can measure the force provided from the air cylinder 50-12 to the shaft 50-1.

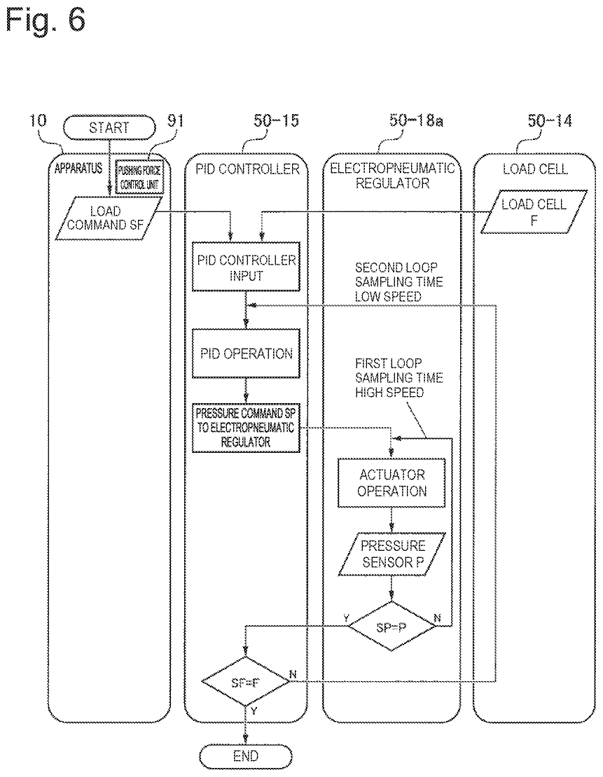

As one embodiment, the PID control can be performed on the contact pressure between the catalyst holding head 30 and the wafer W. FIG. 6 is a flowchart depicting a flow of performing the PID control on the contact pressure between the catalyst holding head 30 and the wafer W as one embodiment. As depicted in the flowchart of FIG. 6, the PID controller 50-15 receives a load command SF from the pushing force control unit 91 in the substrate processing apparatus 10. Meanwhile, the PID controller 50-15 receives a measured force F from the load cell 50-14. The PID controller 50-15 performs a PID operation to achieve the received load command SF inside the PID controller. Based on the PID operation result, the PID controller 50-15 provides the electropneumatic regulator 50-18a with a pressure command SP. The electropneumatic regulator 50-18a that has received the pressure command SP operates an internal actuator to discharge the air at a predetermined pressure P. Note that the electropneumatic regulator 50-18a internally holds a pressure sensor, and feedback control is performed such that the pressure P of the air discharged from the electropneumatic regulator 50-18a becomes equal to the pressure command SP. The feedback control is performed in comparatively high-speed sampling time. The air discharged by the electropneumatic regulator 50-18a is supplied to the air cylinder 50-12 to drive the air cylinder. The load cell 50-14 measures the force F generated by the air cylinder 50-12. The PID controller 50-15 compares the measured value F received from the load cell 50-14 with the load command SF received from the pushing force control unit 91 and repeats a process at and after the PID operation until both become equal. The feedback control is performed in sampling time at a rate lower than the above-described internal feedback control of the electropneumatic regulator 50-18a. By thus monitoring the pushing force of the catalyst holding head 30 to the wafer W and performing the feedback control using the load cell 50-14 and the PID controller 50-15, the optimal pushing force can be always maintained. Note that, to control a driving speed of the air cylinder 50-12, the load command can be changed in phases (for example, per 0.1 seconds) to ensure reaching the final load command SF.

As illustrated in FIG. 2, the conditioning member 60 conditions the surface of the catalyst 31 at a predetermined timing. The conditioning member 60 is disposed outside the wafer W held to the stage 20. The catalyst 31 held to the catalyst holding head 30 can be disposed on the conditioning member 60 by the swing arm 50. In this embodiment, the conditioning member 60 includes a scrub cleaning member 61. The scrub cleaning member 61 includes a sponge, a brush, and the like, and performs scrub cleaning on the catalyst 31 in the presence of the cleaning liquid supplied from a cleaning liquid supply member 62. A contact between the catalyst holding head 30 and the scrub cleaning member 61 at this time is performed by vertical movement of the catalyst holding head 30 side or the scrub cleaning member 61. During the conditioning, at least one of the catalyst holding head 30 or the scrub cleaning member 61 is relatively moved, such as a rotation. This allows recovering the surface of the catalyst 31 to which an etching product attaches to an active state and also allows suppressing damage to the processed region of the wafer W due to the etching product.

The conditioning member 60 can employ various kinds of configurations, not limited to the above-described configuration. For example, although water is basically sufficient as this cleaning liquid in the scrub cleaning member 61, there may be a case where a removal of the etching product is difficult only by scrub cleaning depending on the etching product. In such a case, liquid medicine that can remove the etching product may be supplied as the cleaning liquid. For example, when the etching product is silicate (SiO₂), hydrofluoric acid may be used as the liquid medicine. Alternatively, the conditioning member 60 may include an electrolytic regeneration unit that removes the etching product on the surface of the catalyst 31 using an electrolytic action. Specifically, the electrolytic regeneration unit includes an electrode that can be electrically connected to the catalyst 31, and an application of a voltage between the catalyst and the electrode removes the etching product attached to the surface of the catalyst 31.

Alternatively, the conditioning member 60 may include a plating regeneration unit that newly plates the catalyst 31 to regenerate the catalyst 31. This plating regeneration unit includes an electrode that can be electrically connected to the catalyst 31, and an application of a voltage between the catalyst 31 and the electrode with the catalyst 31 dipped in a liquid containing a catalyst for regeneration regenerates the plating of the surface of the catalyst 31.

The control unit 90 controls the general operations of the substrate processing apparatus 10. The control unit 90 also controls parameters regarding etching process conditions of the wafer W. Examples of the parameters include a movement condition, such as the rotation, of the stage 20 and the catalyst holding head 30, the contact pressure between the catalyst 31 and the wafer W, the swing condition of the swing arm 50, supply conditions, such as the flow rate of the process liquid from the process liquid supply member 40 and a process liquid temperature, a conditioning condition of the catalyst surface by the conditioning member 60, and the like.

The control unit 90 includes the pushing force control unit 91 that controls the force of pushing the catalyst holding head 30 against the surface to be processed of the wafer W. The pushing force control unit 91 adjusts the pushing force of the catalyst holding head 30 by the pushing mechanism 52 according to the position of the catalyst holding head 30 when the swing mechanism 55 swings the catalyst holding head 30 or the contact area between the wafer Wand the catalyst 31. Hereinafter, this point will be described.

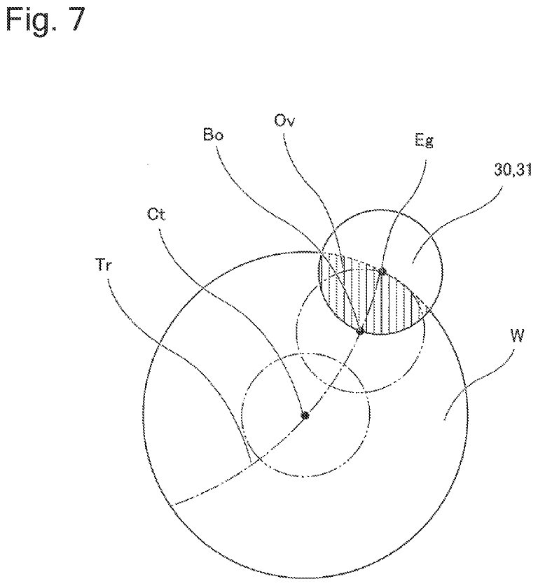

In this embodiment, since the catalyst holding head 30 and the catalyst 31 are smaller than the wafer W, to perform the etching process on the whole surface of the wafer W, the substrate processing apparatus 10 swings the catalyst holding head 30 in the radial direction of the wafer W using the swing mechanism 55. Here, the substrate processing apparatus 10 of this embodiment swings (overhangs) the catalyst holding head 30 until the catalyst holding head 30 projects to outside the wafer W to uniformly process the surface to be processed of the wafer W. FIG. 7 is a drawing schematically illustrating a state of overhanging the catalyst holding head 30 from the wafer W. As illustrated in FIG. 7, the catalyst holding head 30 swings on the wafer W along a trajectory Tr and overhangs until the catalyst holding head 30 (catalyst 31) projects from the wafer W. When the catalyst holding head 30 is overhung from the wafer W, since a structure to support the catalyst holding head 30 is absent outside the wafer W, a strong pressure is applied to a contact region Ov between the wafer W and the catalyst 31. Then, an excessive scratch occurs between the outer peripheral portion of the wafer W and the catalyst 31, and this causes an abrasion of the catalyst 31 and peeling of the catalyst 31 from the catalyst holding head 30. Consequently, the wafer W is possibly damaged and the surface to be processed of the wafer W is possibly damaged. This problem never occurs in a CMP apparatus, which does not use a catalyst to polish a substrate by relative movement between a polishing pad and the substrate, but is a problem specific to the substrate processing apparatus employing the CARE technique.

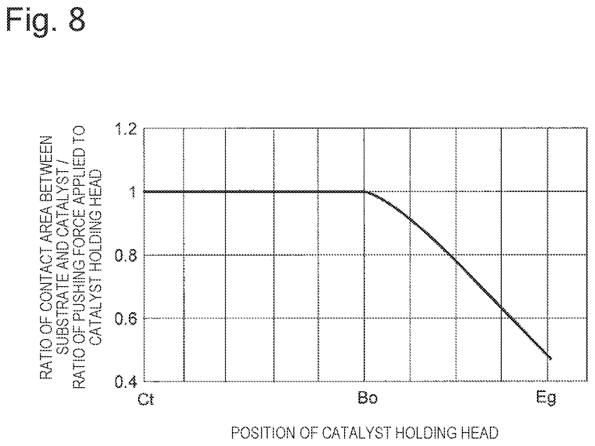

In contrast to this, in this embodiment, the pushing force control unit 91 adjusts the pushing force of the catalyst holding head 30 by the pushing mechanism 52 such that the pressure applied to the contact region Ov between the wafer W and the catalyst 31 becomes constant. FIG. 8 is a graph showing a ratio of the contact area between the wafer W and the catalyst 31 and a ratio of the pushing force of the catalyst holding head 30 to the position of the catalyst holding head 30. FIG. 8 plots the position of the catalyst holding head 30 on the horizontal axis. The vertical axis plots the ratio of the contact area between the wafer W and the catalyst 31 with the contact area when the whole catalyst 31 contacts the wafer W is 1, and the ratio of the pushing force applied to the catalyst holding head 30 with the pushing force when the whole catalyst 31 contacts the wafer W is 1.

As illustrated in FIG. 8, the ratio of the contact area between the wafer W and the catalyst 31 does not change and the pushing force applied to the catalyst holding head 30 does not change either from a state in which the center of the catalyst holding head 30 is at a center position Ct of the wafer W until the catalyst holding head 30 (catalyst 31) reaches a position Bo where the catalyst holding head 30 (catalyst 31) starts projecting to outside the wafer W. Meanwhile, from the state in which the center of the catalyst holding head 30 is at the position Bo until the catalyst holding head 30 reaches a position Eg where the catalyst holding head 30 is overhung the most, the ratio of the contact area between the wafer W and the catalyst 31 gradually decreases, and the pushing force applied to the catalyst holding head 30 also gradually decreases. That is, the pushing force control unit 91 reduces the pushing force of the catalyst holding head 30 by the pushing mechanism 52 as the position of the catalyst holding head 30 is away from the center position of the wafer W with the catalyst 31 projecting to outside the wafer W. Meanwhile, the pushing force control unit 91 increases the pushing force of the catalyst holding head 30 by the pushing mechanism 52 as the position of the catalyst holding head 30 approaches the center position of the wafer W with the catalyst 31 projecting to outside the wafer W. In other words, the pushing force control unit 91 reduces the pushing force of the catalyst holding head 30 by the pushing mechanism 52 as the contact area between the wafer W and the catalyst 31 decreases, and increases the pushing force of the catalyst holding head 30 by the pushing mechanism 52 as the contact area between the wafer W and the catalyst 31 increases.

As one example, the pushing force control unit 91 is configured to calculate the position of the catalyst holding head 30 based on a rotation angle of the swing arm 50. The pushing force control unit 91 is configured to calculate the contact area between the wafer W and the catalyst 31 based on the position of the catalyst holding head 30 and a diameter of the catalyst 31. This, however, should not be construed in a limiting sense. For example, the pushing force control unit 91 can detect the position of the catalyst holding head 30 using a position sensor mounted to the catalyst holding head 30. While this embodiment shows an example in which the pushing force of the catalyst holding head 30 by the pushing mechanism 52 is adjusted according to the position of the catalyst holding head 30 or the contact area between the wafer Wand the catalyst 31. This, however, should not be construed in a limiting sense. The pushing force control unit 91 can adjust the pushing force of the catalyst holding head 30 by the pushing mechanism 52 according to a moving distance from a swing start position of the catalyst holding head 30 (for example, a position corresponding to the center of the wafer W). In this case, the pushing force control unit 91 can calculate the moving distance of the catalyst holding head 30 based on the rotation angle of the swing arm 50 from the start of swinging of the catalyst holding head 30, and the contact area between the wafer W and the catalyst 31 can be calculated based on the moving distance of the catalyst holding head 30 and the diameter of the catalyst 31.

According to this embodiment, the pushing force of the catalyst holding head 30 by the pushing mechanism 52 can be adjusted according to the degree of overhang of the catalyst holding head 30. Accordingly, even when the catalyst holding head 30 is overhung, the pressure applied to the contact region Ov between the wafer W and the catalyst 31 can be held constant. Accordingly, this embodiment allows preventing an excessive scratch between the outer peripheral portion of the wafer W and the catalyst 31, and as a result, the excessive abrasion of the catalyst 31 and the peeling of the catalyst 31 from the catalyst holding head 30 can be prevented, thereby ensuring suppressing the damage of the wafer W and the damage to the surface to be processed.

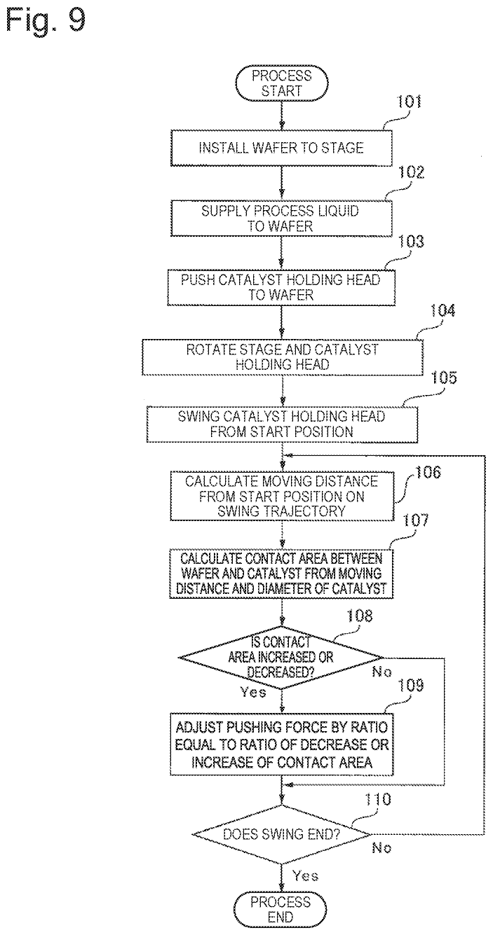

Next, the flow of the etching process of the substrate by the substrate processing apparatus 10 will be described. FIG. 9 is a flowchart depicting the substrate processing method by the substrate processing apparatus 10. As illustrated in FIG. 9, when the etching process starts, first, the wafer W is installed to the stage 20 with the surface to be processed upward and is held by vacuum suction (installing step 101). Next, the process liquid is supplied on the wafer W by the process liquid supply member 40 (supplying step 102). Next, after the catalyst 31 mounted to the catalyst holding head 30 is disposed at a predetermined position on the wafer W with the swing arm 50, the catalyst holding head 30 is pushed against the surface to be processed of the wafer W (pushing step 103). Simultaneous with the pushing step 103 or after the pushing step 103, the stage 20 is rotated and the catalyst holding head 30 is also rotated (relative movement step 104). Next, the catalyst holding head 30 is swung from the swing start position in the radial direction of the wafer W by the swing mechanism 55 (swinging step 105).

Next, the moving distance from the swing start position on the swing trajectory Tr of the catalyst holding head 30 is calculated by the pushing force control unit 91 (moving distance calculating step 106). For example, the pushing force control unit 91 can calculate the moving distance of the catalyst holding head 30 from the swing start position to the current position of the catalyst holding head 30. Next, based on the moving distance of the catalyst holding head 30 and the diameter of the catalyst 31, the pushing force control unit 91 calculates the contact area between the wafer W and the catalyst 31 (contact area calculating step 107). Next, whether the contact area is increased or decreased is determined by the pushing force control unit 91 (determining step 108). When it is determined that the contact area is increased or decreased (determining step 108, Yes), the pushing force of the catalyst holding head 30 by the pushing mechanism 52 is adjusted so as to be a ratio equal to a ratio of the increase or the decrease of the contact area by the pushing force control unit 91 (adjusting step 109). When it is determined that the contact area is not increased or decreased after the adjusting step 109 or in the determining step 108, that is, when the catalyst holding head 30 is not overhung (determining step 108, No), whether the swing of the catalyst holding head 30 ends is determined by the pushing force control unit 91 (determining step 110). When it is determined that the swing of the catalyst holding head 30 does not end (determining step 110, No), the process returns to the moving distance calculating step 106 and the process is continued. Meanwhile, when it is determined that the swing of the catalyst holding head 30 ends (determining step 110. No) the etching process ends.

By the operations, an etchant generated by the action of the catalyst 31 at the contact portion between the wafer W and the catalyst 31 by the catalytic action of the catalyst 31 acts on the wafer W surface, thus performing etching removal on the surface of the wafer W. The processed region of the wafer W can be constituted of any single or a plurality of materials. Examples of the materials include an insulating film typified by SiO₂ and a Low-k material, a wiring metal typified by Cu and W, a barrier metal typified by Ta, Ti, TaN, TiN, Co, and the like, and a III-V group material typified by GaAs and the like. Examples of the material of the catalyst 31 can include a noble metal, a transition metal, a ceramic-based solid catalyst, a basic solid catalyst, an acid solid catalyst, and the like. Examples of the process liquid PL can include oxygen dissolved water, ozone water, acid, an alkaline solution, H₂O₂ water, a hydrofluoric acid solution, and the like. Note that the catalyst 31 and the process liquid PL can be appropriately set according to the material of the processed region of the wafer W. For example, when the material of the processed region is Cu, the acid solid catalyst may be used as the catalyst 31 and ozone water may be used as the process liquid PL. When the material of the processed region is SiO₂, platinum and nickel are used as the catalyst 31 and acid may be used as the process liquid PL. When the material of the processed region is the III-V group metal (for example, GaAs), iron may be used as the catalyst 31 and H₂O₂ water may be used as the process liquid PL.

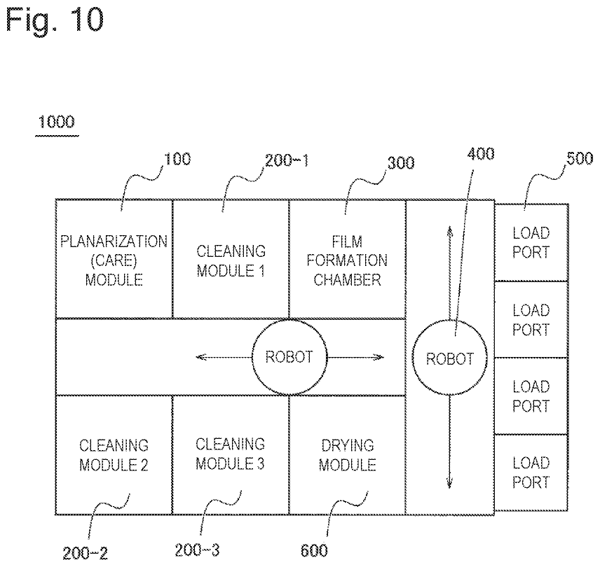

FIG. 10 is a plan view illustrating a schematic configuration of a substrate processing system as one embodiment. A substrate processing system 1000 illustrated in the drawing includes a CARE module 100 that performs the etching process on the substrate as described in this specification, a plurality of cleaning modules 200 that clean the substrate, a film formation chamber 300, robots 400 as a conveyance mechanism of the substrate, load ports 500 of the substrate, and a drying module 600. The wafer W to be processed by the system configuration is put into the load port 500. The wafer loaded to the load port 500 is conveyed to the film formation chamber 300 by the robot 400, and the film formation process is performed in the film formation chamber 300. Examples of the film formation chamber 300 can include a chemical vapor deposition (CVD) apparatus, a sputtering apparatus, a plating apparatus, a coater apparatus, or the like. The wafer W on which the film formation process has been performed is conveyed to a first cleaning module 200-1 by the robot 400 for cleaning. Afterwards, the wafer W is conveyed to a planarization module 100, namely, a CARE processing module as described in this specification for a planarization process. Afterwards, the wafer W is conveyed to a second cleaning module 200-2 and/or a third cleaning module 200-3 for cleaning. The wafer W on which the cleaning process has been performed is conveyed to the drying module 600 for drying. The dried wafer W is returned to the load port 500 again. This system allows performing the film formation process and the planarization process of the wafer W by one system, and therefore an installation area can be efficiently utilized. The conveyance mechanism can separately convey the substrate in a wet state and the substrate in a dry state.

The following describes embodiments of the substrate processing apparatus with reference to the attached drawings. In the attached drawings, identical or similar reference numerals are attached to identical or similar components, and overlapping description regarding the identical or similar components may be omitted in the description of the respective embodiments. Features illustrated in the respective embodiments are applicable to other embodiments in so far as they are consistent with one another. Note that, in the description of the following embodiments of this specification, a “substrate” includes a magnetic recording medium, a magnetic recording sensor, a mirror, an optical element, a micro mechanical element, or a partially fabricated integrated circuit, not only a semiconductor substrate, a glass substrate, or a printed circuit board.

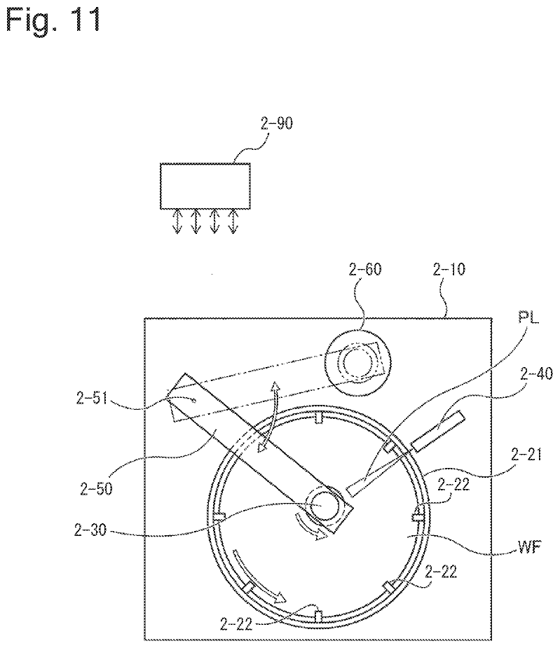

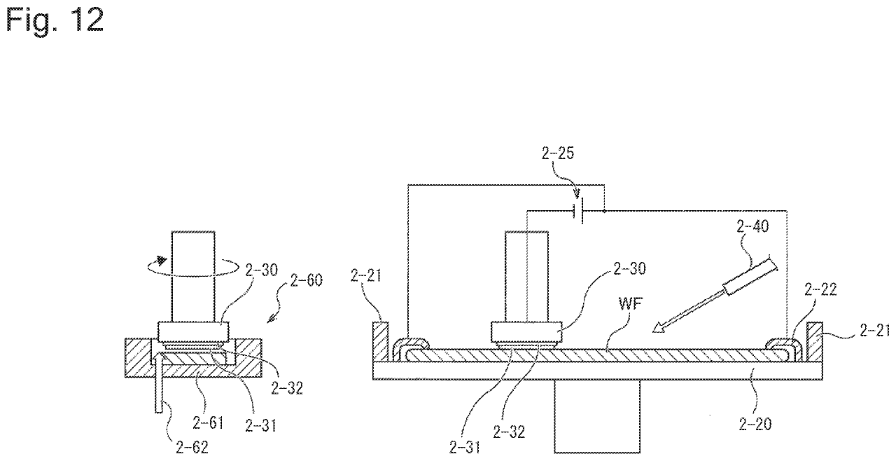

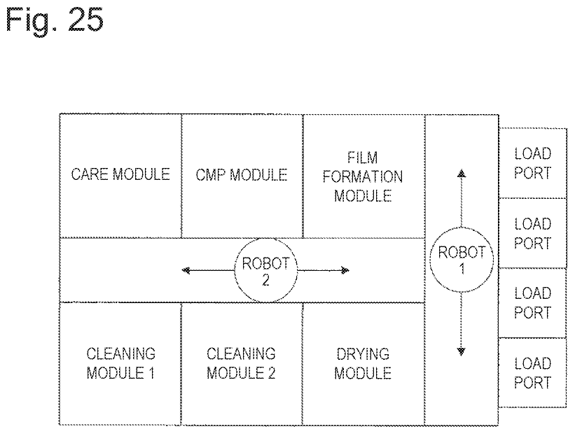

FIG. 11 is a schematic plan view of a substrate processing apparatus 2-10 according to one embodiment. FIG. 12 is a side view of the substrate processing apparatus 2-10 illustrated in FIG. 11. The substrate processing apparatus 2-10 is an apparatus that performs the etching process on the surface of a substrate WF using the CARE method. The substrate processing apparatus 2-10 can be configured as a part of the substrate processing system. FIG. 25 is a block diagram schematically illustrating the substrate processing system according to one embodiment. The substrate processing system includes load ports, a CMP module, a CARE module, a film formation module, cleaning modules, and a drying module. The substrate processing system includes robots that convey the substrate inside the substrate processing system. In the substrate processing system illustrated in FIG. 25, the load port holds the substrate before the process and holds the substrate after the process. A robot 2-1 can receive the substrate before the process from the load port and pass the substrate to a robot 2-2. The robot 2-2 can convey the substrate between the film formation module, the CMP module, the CARE module, the cleaning modules 2-1, 2-2, the drying module, and the robot 2-1. The CARE module in the substrate processing system can include any feature of the substrate processing apparatus 2-10 described later. Any configuration can be used as a configuration in the substrate processing system other than the CARE module, and the type and the number of the modules may be arbitrarily set.

The substrate processing apparatus 2-10 illustrated in FIG. 11 and FIG. 12 includes a table 2-20 that holds the substrate WF, a head 2-30 that holds a catalyst 2-31, a nozzle 2-40 that supplies the process liquid PL on the substrate WF held to the table 2-20, an arm 2-50 that swings the head 2-30 in a direction parallel to the substrate, a conditioner 2-60, and a control device 2-90.

The table 2-20 holds the substrate WF. In the embodiment illustrated in the drawing, the table 2-20 holds the substrate WF with the surface to be processed upward. In the embodiment illustrated in the drawing, the table 2-20 includes a vacuum suction mechanism that includes a vacuum suction plate that performs vacuum suction on a back surface (a surface on a side opposite to the surface to be processed) of the substrate WF as a mechanism that holds the substrate WF. For stabilization of the suction state, a backing material may be pasted to a suction plate surface, and the substrate WF may be suctioned to the table 2-20 via this backing material. The mechanism that holds the substrate WF on the table 2-20 can be any known mechanism, and may be, for example, a clamp mechanism that clamps a front surface and the back surface of the substrate WF by at least one part of a peripheral edge portion of the substrate WF, or may be a roller chuck mechanism that holds a side surface of the substrate WF by at least one part of the peripheral edge portion of the substrate WF. The table 2-20 is rotatably configured by a driving unit motor and an actuator (not illustrated).

In this drawing, the table 2-20 includes a wall 2-21 that extends vertically upward in the whole circumferential direction outside a region to hold the substrate WF. This allows holding the process liquid PL inside the surface of the substrate WF, and as a result, usage of the process liquid PL can be reduced. While the wall 2-21 is fixed to an outer periphery of the table 2-20 in this drawing, the wall 2-21 may be configured separately from the table. In the case, the wall 2-21 may be configured to vertically move. The wall 2-21 configured to vertically move allows changing an amount of the held process liquid PL, and, for example, when the substrate surface after the etching process is cleaned with pure water and cleaning liquid, lowering the wall 2-21 allows efficiently discharging the cleaning liquid to outside the substrate WF.

In the embodiment illustrated in FIG. 1I and FIG. 12, the head 2-30 has a lower end holding the catalyst 2-31. In this embodiment, the catalyst 2-31 is smaller than the substrate WF. That is, a projection area of the catalyst 2-31 when projected from the catalyst 2-31 to the substrate WF is smaller than an area of the substrate WF. The head 2-30 is configured to be rotatable by a driving unit, namely, an actuator (not illustrated). Additionally, the arm 2-50 described later includes a motor and an air cylinder (not illustrated) that cause the catalyst 2-31 of the head 2-30 to contact and slide to the substrate WF.

In one embodiment, the catalyst 2-31 can be a single base metal and/or an alloy mainly containing a base metal. For example, in one embodiment, the catalyst 2-31 can be a single metal containing one or an alloy mainly containing one selected from the group consisting of titanium (Ti), chrome (Cr), molybdenum (Mo), tungsten (W), nickel (Ni), vanadium (V), iron (Fe), cobalt (Co), copper (Cu), hafnium (H), and tantalum (Ta). In one embodiment, in the case where the catalyst 2-31 is an alloy, the catalyst 2-31 can be an alloy mainly containing any one of the above-described metals and further containing at least one selected from the group consisting of ruthenium (Ru), rhodium (Rh), palladium (Pd), argentum (Ag), iridium (Ir), platinum (Pt), and aurum (Au).

In one embodiment, the catalyst 2-31 is fixed to a surface of a base member 2-32 having a reference surface. In one embodiment, the catalyst 2-31 is formed on the surface of the base member 2-32 by any one of methods of a sputtering method, a chemical vapor deposition method (CVD), a vapor deposition method, and a plating method. When the catalyst 2-31 is formed on the surface of the base member 2-32 using the sputtering method, a plurality of metallic materials serving as a catalyst may be simultaneously sputtered, another metallic material may be disposed on a certain metallic material and sputtered, or an alloy material may be sputtered. Alternatively, after stacking layers of different metal elements, a heating process may be performed to form an alloy layer. When the catalyst 2-31 is formed on the base member 2-32 having the reference surface, the base member 2-32 may be made of an elastic material having elasticity, such as a rubber and a sponge. The use of the elastic member as the base member 2-32 relatively increases the contact pressure at a projecting portion on the surface of the substrate WF as the process target, and the projecting portion is selectively removed. On the surface of the base member 2-32 to which the catalyst 2-31 held, a groove having any pattern is preferably provided. By providing the groove, the process liquid to be supplied passes through the inside of the groove, and thus the process liquid is efficiently supplied between the surface of the catalyst 2-31 and the surface of the substrate WF as the process target. In one embodiment, a foil of the catalyst 2-31 may be fixed to the base member 2-32 made of an elastic material with an adhesive or the like. In this case, while the reference surface follows the surface shape of the substrate WF as the process target, peeling of the catalyst 2-31 caused by expansion and contraction of the elastic body can be suppressed. Although the head 2-30 is one in the embodiment illustrated in FIG. 12, a plurality of the heads 2-30 may be used for the process. In this case, the catalysts 2-31 of the respective heads 2-30 may be identical, or may be different catalysts depending on exposed materials of the substrate WF as the process target. When the catalysts 2-31 of the respective heads 2-30 are identical, an area that the catalysts 2-31 cover the substrate WF increases, and therefore a process speed increases. Alternatively, when the catalysts 2-31 of the respective heads 2-30 differ, even when a plurality of etching targets are exposed, an action of each of the catalysts 2-31 allows adjustment of the etching rate of each material.

Next, the nozzle 2-40 supplies the surface of the substrate WF with the process liquid PL. Here, although the nozzle 2-40 is one in the embodiment illustrated in FIG. 11 and FIG. 12, a plurality of the nozzles 2-40 may be disposed, and in the case, different process liquids may be supplied from the respective nozzles 2-40 according to the process steps. Different process liquids may be supplied from the respective nozzles and the supplied flow rates of the process liquids from the respective nozzles 2-40 may be changed according to the process step to change a composition ratio of the mixed process liquid. When the process liquids are supplied from the plurality of nozzles 2-40, the process liquids supplied from the respective nozzles may be selected according to the process step to change the composition of the process liquid. Additionally, when the surface of the substrate WF is cleaned in the substrate processing apparatus 2-10 after the etching process, liquid medicine for cleaning and water may be supplied from the nozzle 2-40. In one embodiment, the process liquid can be a liquid produced by mixing a liquid containing a compound having an oxidizing property, and an electrolyte. One example of the liquid containing the compound having the oxidizing property can include at least one of hydrogen peroxide or ozone water. The electrolyte to be mixed can include at least one of acid electrolyte, neutral electrolyte, and basic electrolyte. Examples of the acid electrolyte can include at least one of inorganic acid, such as hydrochloric acid, nitric acid, sulfuric acid, and phosphoric acid, or water-soluble organic acid containing fatty acid, such as citric acid, oxalic acid, formic acid, and acetic acid. Examples of the neutral electrolyte can include at least one of potassium chloride, sodium chloride, or sodium sulfate. Examples of the basic electrolyte can include at least one of inorganic acid, such as potassium hydroxide, sodium hydroxide, or calcium hydroxide, or any organic matter, such as ammonia. A pH of the process liquid is preferably adjusted in a range of from 1 or more to 14 or less. Note that when process liquids having a plurality of compositions or different composition ratios are used according to the process step, a step of cleaning the surface of the substrate WF may be inserted between the respective process steps. Providing the cleaning step allows preventing a mixture of the process liquid used in the previous step and the process liquid that will be used in the next step. Regarding each process liquid, a temperature of each process liquid may be adjusted by a temperature control mechanism (not illustrated).

Next, the arm 2-50 is swingable around a rotational center 2-51 and configured to move up and down by the driving unit, namely, the actuator (not illustrated). Here, in this embodiment, since the catalyst 2-31 is smaller than the substrate WF, when the etching process is performed on the whole surface of the substrate WF, the head 2-30 swings on the whole surface of the substrate WF. Here, this CARE method generates etching only in the contact portion where that catalyst contacts the substrate WF. Accordingly, the distribution of the contact period between the substrate WF and the catalyst 2-31 in the surface of the substrate WF in the respective regions of the substrate WF significantly affects the distribution of the amount of etching in the surface of the wafer in the respective regions of the substrate WF. Regarding this point, making a swing rate of the arm 2-50 in the surface of the wafer variable allows uniforming the distribution of the contact period. Specifically, a swing range of the arm 2-50 in the surface of the substrate WF is divided into a plurality of sections, and the swing rate is controlled in each section. The arm 2-50 has a distal end (an end portion on a side opposite to the rotational center 2-51) to which the head 2-30 is rotatably mounted.

In the embodiment illustrated in FIG. 12, the substrate processing apparatus 2-10 includes a plurality of electrodes 2-22 that contact a conductive layer on the surface of the substrate WF disposed on the table 2-20. The plurality of electrodes 2-22 are disposed, for example, at regular intervals in the circumferential direction of the substrate WF. The electrodes 2-22 rotate together with the table 2-20. Therefore, since the electrodes 2-22 and the substrate WF do not relatively move, and thus a risk that an electrode 2-22 damages the surface of the substrate WF can be reduced. In one embodiment, the electrodes 2-22 may be fixed to the table 2-20. As illustrated in the drawing, the electrodes 2-22 are electrically connected to a power source 2-25. Regarding polarity, in one embodiment, the electrodes 2-22 are connected to a positive side of the power source 2-25, and the catalyst 2-31 held to the head 2-30 is electrically connected to a negative side of the power source 2-25. However, the polarity may be changed depending on the exposed state of the etching target material of the substrate WF. With this configuration, the substrate processing apparatus 2-10 can flow a current through the catalyst 2-31 from the electrodes 2-22 through the conductive layer on the substrate WF. Flowing the current through the substrate WF and the catalyst adds etching by electrolytic reaction to the etching by CARE, thereby ensuring further highly efficient process. In one embodiment, the electrodes 2-22 may be configured so as to contact the process liquid but not to contact the substrate WF. In this case, the catalyst 2-31 and the electrode 2-22 are electrochemically connected via the process liquid. With the configuration, a surface potential of the catalyst 2-31 is controlled to be in a predetermined range. This allows preventing an attachment of a factor that inhibits activation of the surface of the catalyst 2-31 and controlling a process speed.

The conditioner 2-60 conditions the surface of the catalyst 2-31 at a predetermined timing. This conditioner 2-60 is disposed outside the substrate WF held to the table 2-20. The catalyst 2-31 held to the head 2-30 can be disposed on the conditioner 2-60 by the arm 2-50.

In the embodiment illustrated in FIG. 12, the conditioner 2-60 includes a scrub cleaning unit 2-61. The scrub cleaning unit 2-61 includes a scrub member, such as a sponge and a brush, and performs scrub cleaning on the catalyst 2-31 in the presence of a conditioning liquid supplied from a cleaning liquid supply unit 2-62. A contact between the head 2-30 and the scrub member of the scrub cleaning unit 2-61 at this time is performed by vertical movement of the head 2-30 side or the scrub member. During the conditioning, at least one of the head 2-30 or the scrub member of the scrub cleaning unit 2-61 is relatively moved, such as a rotation. This allows recovering the surface of the catalyst 2-31 to which an etching product attaches to an active state and also allows suppressing damage to the processed region of the substrate WF due to the etching product.

The conditioner 2-60 can employ various kinds of configurations, not limited to the above-described configuration. For example, although water is basically sufficient as the conditioning liquid in the scrub cleaning unit 2-61, there may be a case where a removal of the etching product is difficult only by scrub cleaning depending on the etching product. In such a case, liquid medicine that can remove the etching product may be supplied as the cleaning liquid. For example, when the etching product is silicate (SiO₂), hydrofluoric acid may be used as the liquid medicine. Alternatively, the conditioner 2-60 may include an electrolytic regeneration unit that removes the etching product on the surface of the catalyst 2-31 using an electrolytic action. Specifically, the electrolytic regeneration unit includes an electrode that can be electrically connected to the catalyst 2-31, and an application of a voltage between the catalyst and the electrode removes the etching product attached to the surface of the catalyst 2-31. When the electrolytic reaction is same as a removal reaction of the etching product with the conditioning liquid, the conditioning speed can be promoted by electric energy. Alternatively, when the electrolytic reaction is a different reaction from the removal reaction of the etching product with the conditioning liquid, addition of the electrolytic reaction to the etching reaction with the conditioning liquid increases the conditioning speed, and the catalyst 2-31 can be conditioned in a short time.

Alternatively, the conditioner 2-60 may include a plating regeneration unit that newly plates the catalyst 2-31 to regenerate the catalyst 2-31. This plating regeneration unit includes an electrode that can be electrically connected to the catalyst 2-31, and an application of a voltage between the catalyst 2-31 and the electrode with the catalyst 2-31 dipped in a liquid containing a catalyst for regeneration regenerates the plating of the surface of the catalyst 2-31.

The control device 2-90 controls the general operations of the substrate processing apparatus 2-10. The control device 2-90 can include a general-purpose computer, a dedicated computer, or the like. The control device 2-90 also controls parameters regarding etching process conditions of the substrate WF. Examples of the parameters include a movement condition, such as a rotation and an angle rotation of the head 2-30, the contact pressure between the catalyst 2-31 and the substrate WF, the swing condition of the arm 2-50, supply conditions, such as the flow rate of the process liquid from the nozzle 2-40 and a process liquid temperature, an electric potential condition provided between the substrate WF and the catalyst 2-31, and a conditioning condition of the catalyst surface by the conditioner 2-60.

### Working Example

A catalyst referred etching was performed on substrates using different kinds of single metal catalysts. As process targets, the substrates including a ruthenium (Ru) layer, a cobalt (Co) layer, a TiN layer, and a tetraethoxysilane (TEOS) layer on their surfaces were used. As process liquids, acid, neutral, and basic process liquids were used. The single metals used as the catalysts were platinum (Pt), titanium (Ti), chrome (Cr), molybdenum (Mo), tungsten (W), and nickel (Ni). In the catalyst referred etching (CARE), in a state where the substrate including a processed layer as the process target (each layer of Ru, Co, TiN, and TEOS) contacted each catalyst while the substrate and each catalyst were mutually rotated under the presence of the process liquid, a head that held the catalyst was slid. In this working example, the CARE process was performed for one minute in one time. That is, in the one-time process, while the catalyst and the processed layer were relatively moved in the process liquid, they were brought into contact for one minute. Note that the CARE process does not apply a voltage to the catalyst. After the end of the process, the substrate and the catalyst were quickly separated. After the end of the process, the process liquid was quickly removed, and a surface of the substrate was cleaned with ultrapure water. Afterwards, the substrate was quickly dried, and a thickness of the processed layer was measured using an optical interference film thickness meter. The one-minute CARE process was performed five times for each catalyst. Note that the CARE process was performed five times using the identical catalyst. The measurement of the thickness of the processed layer before and after the CARE process finds an amount of removal and a removal rate of the processed layer in one-time process.

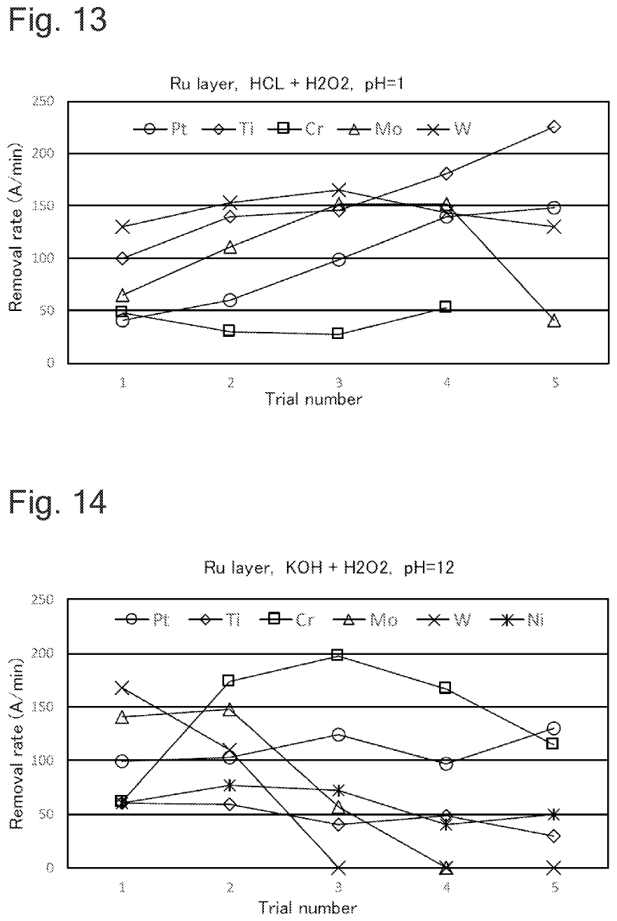

FIG. 13 and FIG. 14 are graphs showing results of the catalyst referred etching using various kinds of single metallic catalysts using the substrate including the ruthenium (Ru) layer on its surface. The process liquid in the working example shown in FIG. 13 contains HCL and H₂O₂ and has a pH of 1. The process liquid in the working example shown in FIG. 14 contains KOH and H₂O₂ and has a pH of 12. FIG. 13 and FIG. 14 plot the number of processes (Trial Number) on the horizontal axis and the removal rate (A/min) on the vertical axis. As seen from FIG. 13, it has been confirmed that the Ru layer can be removed in the presence of the process liquid of HCL+H₂O₂ (pH: 1) using any of Pt, Ti, Cr, Mo, and W as the catalyst. Additionally, as seen from FIG. 14, it has been confirmed that the Ru layer can be removed in the presence of the process liquid of KOH+H₂O₂ (pH: 12) using any of Pt, Ti, Cr, Mo, W, and Ni as the catalyst. In the results of FIG. 13 and FIG. 14, the increase in the number of processes decreases the removal rate in Mo, and W. It is considered that a catalyst metal was etched by the process liquid. As illustrated in FIG. 13, in the CARE of the Ru layer in the acid (pH=1) process liquid, although a comparatively large removal rate is obtained with the Ti, Mo, and W catalysts, from an aspect of chemical stabilization of the catalyst, W, Ti are considered to be especially preferred. As illustrated in FIG. 14, in the CARE of the Ru layer in the basic (pH=12) process liquid, although the comparatively large removal rate is obtained with the Ti, Cr, Mo, W. and Pt, from the aspect of the chemical stabilization of the catalyst, Cr is considered to be especially preferred.

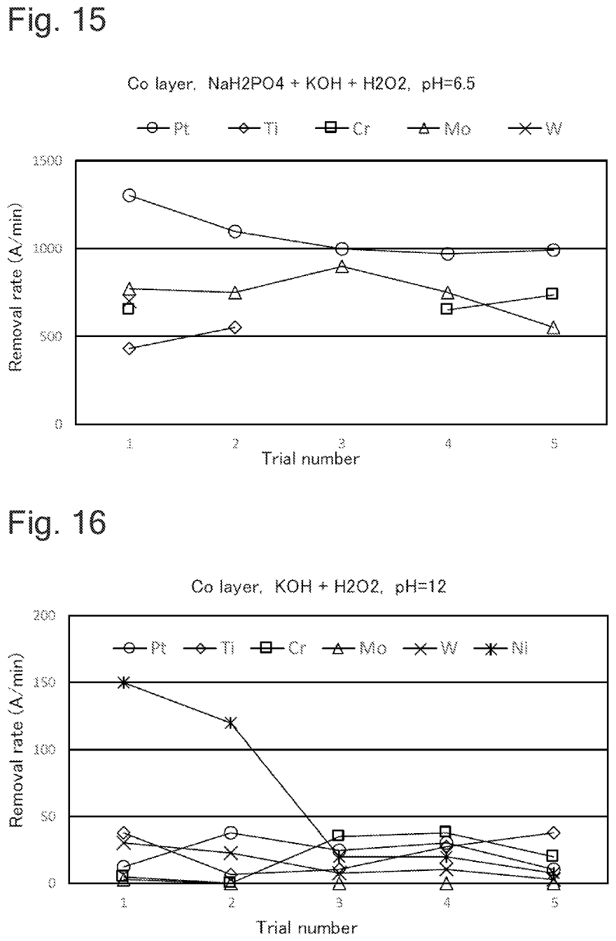

FIG. 15 and FIG. 16 are graphs showing results of the catalyst referred etching using various kinds of single metallic catalysts using the substrate including the cobalt (Co) layer on its surface. The process liquid in the working example shown in FIG. 15 contains NaH₂PO₄, KOH, and H₂O₂ and has a pH of 6.5. The process liquid in the working example shown in FIG. 16 contains KOH and H₂O and has a pH of 12. FIG. 15 and FIG. 16 plot the number of processes (Trial Number) on the horizontal axis and the removal rate (A/min) on the vertical axis. As seen from FIG. 15 and FIG. 16, it has been confirmed that a further high removal rate of the Co layer is obtained in the neutral process liquid. As seen from FIG. 15, in the neutral process liquid, the CARE process can be performed with any of the catalysts Cr, Ti, Mo, or W. Additionally, corrosion occurred in a region not in contact with the catalyst in the Co layer. It is considered from an electric potential-pH diagram (Pourbaix diagram) that a condition of the process liquid in the working example shown in FIG. 15 is in the region in which Co is corroded. Under the condition of the basic (pH=12) process liquid, the removal rate exceeding 100 Å/min was obtained with the Ni catalyst. Note that the removal rate lowers as the number of processes increases. Moreover, since free etching significantly progresses in the Co layer in the acid process liquid, the use of the neutral process liquid allows suppressing the free etching of the Co layer.

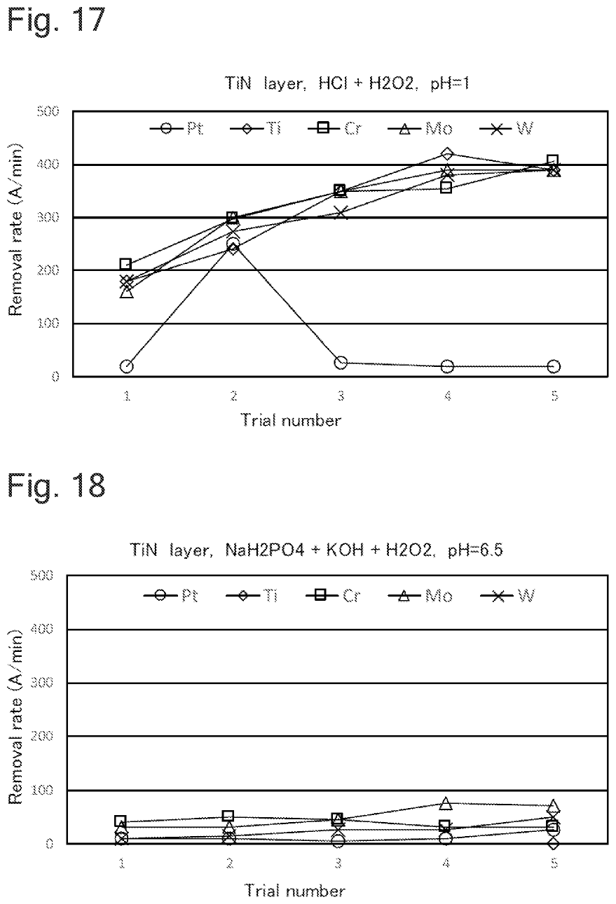

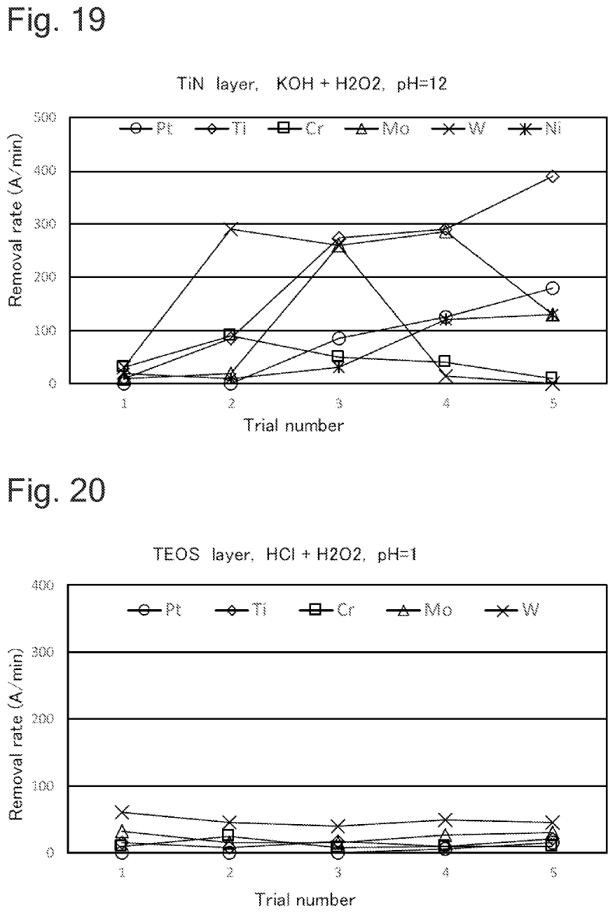

FIG. 17 to FIG. 19 are graphs showing results of the catalyst referred etching using various kinds of single metallic catalysts using the substrate including the TiN layer on its surface. The process liquid in the working example shown in FIG. 17 contains HCL and H₂O₂ and has a pH of 1. The process liquid in the working example shown in FIG. 18 contains NaH₂PO₄, KOH, and H₂O₂, and has a pH of 6.5. The process liquid in the working example shown in FIG. 19 contains KOH and H₂O₂ and has a pH of 12. As seen from FIG. 17 to FIG. 19, the high removal rates were obtained with the various kinds of catalysts under the conditions of the acid (pH=1) and basic (pH=12) process liquids. As seen from FIG. 17, under the condition of the acid process liquid, the comparatively high removal rates were obtained with Cr, Ti, Mo, and W. As seen from FIG. 19, under the condition of the basic process liquid, the removal rates significantly differ depending on the catalysts. Under the condition of the basic process liquid, the CARE can be performed with the catalysts Ti, Mo. W, Ni, and Pt, but the catalysts Mo and W were dissolved, and therefore Ti and Ni are considered to be preferred as the catalyst. In the CARE to remove the TiN layer, an amount (concentration) of hydroxide ion [OH⁻] and/or hydrogen ion [H⁺] probably affects a reaction route and a rate of reaction.

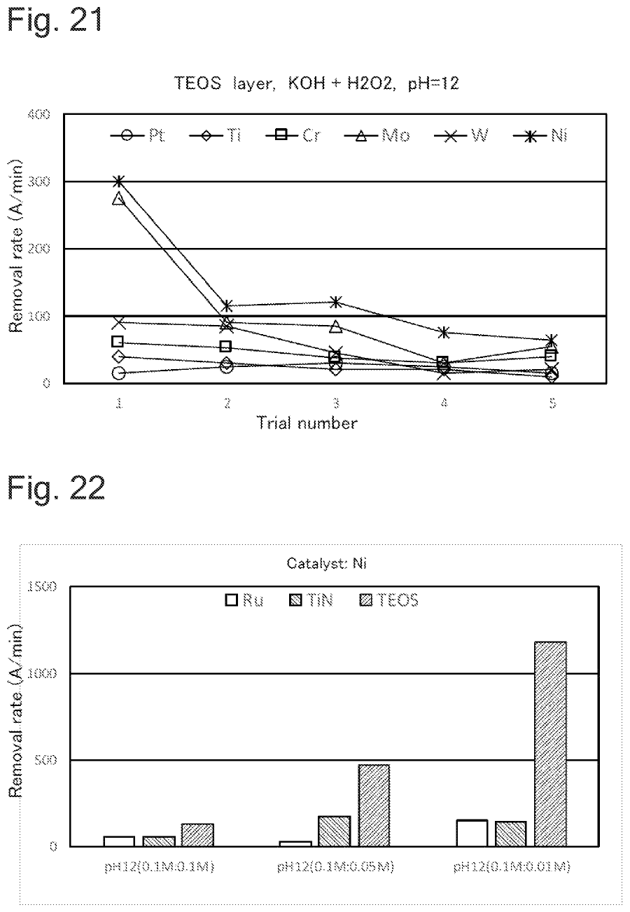

FIG. 20 and FIG. 21 are graphs showing results of the catalyst referred etching using various kinds of single metallic catalysts using the substrate including the TEOS layer on its surface. The process liquid in the working example shown in FIG. 20 contains HCL and H₂O₂ and has a pH of 1. The process liquid in the working example shown in FIG. 21 contains KOH and H₂O₂ and has a pH of 12. As seen from FIG. 21, the large removal rate was obtained with the use of the catalysts Ni and Mo and the use of the basic process liquid. Note that although not illustrated in the graph, with the use of the process liquid of only KOH not using H₂O₂, the removal rate is about 800 Å/min, which is larger than the removal rate under the condition of FIG. 21 in which the process liquid contains H₂O₂. Therefore, H₂O₂ possibly inhibits the CARE reaction. Furthermore, as seen from FIG. 21, the removal rate lowers together with the number of processes. This tendency is a tendency similar to the case of performing the CARE process of SiO₂.

FIG. 22 is a graph showing results of a catalyst referred etching in which component concentrations in process liquids were changed in the respective layers of Ru, TiN, and TEOS. In the working example illustrated in FIG. 22, Ni was used as the catalyst. The process liquid containing KOH and H₂O₂ was used, and three kinds of process liquids having different component concentrations, KOH:H₂O₂=0.1 M:0.1 M, 0.1 M:0.05 M, and 0.1 M:0.01 M were used. The removal rate shown in FIG. 22 indicates an average value of removal rates of the CARE process performed five times for one minute as described above. As seen from FIG. 22, as the concentration of H₂O₂ decreases, the removal rate increases. Under the condition of KOH:H₂O₂=0.1 M:0.01 M, the removal rates exceeding 100 Å/min were obtained in the removal of all layers of Ru, TiN, and TEOS. However, there is a feature that the removal rate of the TEOS layer prominently increases, and therefore the Ni catalyst is considered to be unsuitable for an object of uniformly removing all layers of Ru, TiN, and TEOS.

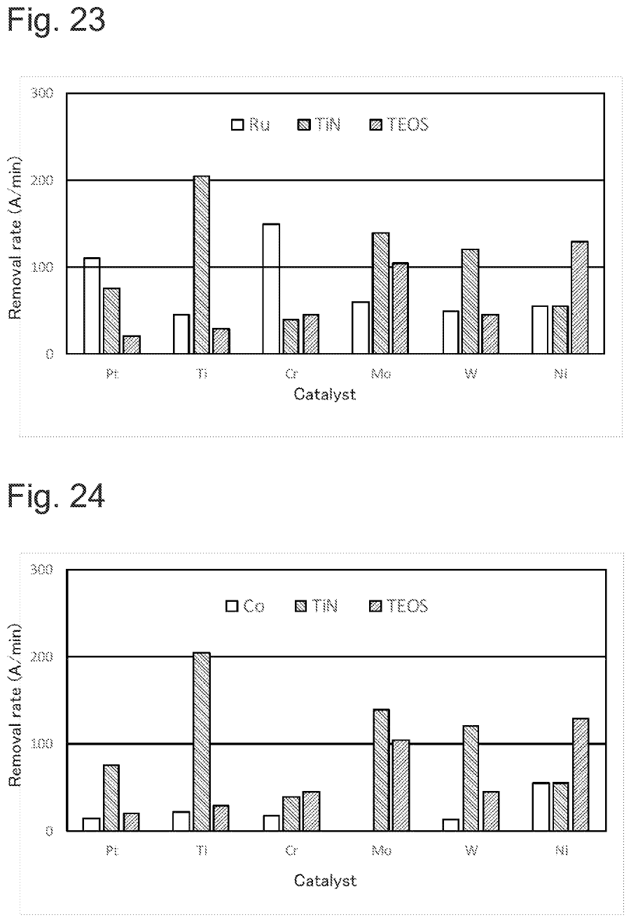

FIG. 23 is a graph that compares removal rates when a CARE process was performed with respective catalysts on the respective layers of Ru, TiN, and TEOS. In the graph illustrated in FIG. 23, the removal rate indicates an average value of removal rates of the CARE process performed five times for one minute. Additionally, in the working example illustrated in FIG. 23, the CARE process was performed under the condition of the basic (pH=12) process liquid. As illustrated in FIG. 23, with the Ni catalyst and the Mo catalyst, an entirely high removal rate in average is achieved for Ru, TiN, and TEOS.

FIG. 24 is a graph that compares removal rates when a CARE process was performed with respective catalysts on the respective layers of Co, TiN, and TEOS. In the graph illustrated in FIG. 24, the removal rate indicates an average value of removal rates of the CARE process performed five times for one minute. Additionally, in the working example illustrated in FIG. 24, the CARE process was performed under the condition of the basic (pH=12) process liquid. As illustrated in FIG. 24, with the Ni catalyst, an entirely high removal rate in average is achieved for Co, TiN, and TEOS.

In the foregoing, several embodiments of the present invention have been described above in order to facilitate understanding of the present invention without limiting the present invention. The present invention can be changed or improved without departing from the gist thereof, and of course, the equivalents of the present invention are included in the present invention. It is possible to arbitrarily combine or omit respective components described in the claims and specification in a range in which at least a part of the above described problems can be solved, or a range in which at least a part of the effects can be exhibited.

[Configuration 1]

This application discloses a substrate processing apparatus as one embodiment that includes a stage, a catalyst holding head, a pushing mechanism, a swing mechanism, and a pushing force control unit. The stage holds a substrate with a surface to be processed upward. The catalyst holding head holds a catalyst to process the surface to be processed of the substrate. The pushing mechanism pushes the catalyst holding head against the surface to be processed of the substrate. The swing mechanism swings the catalyst holding head in a radial direction of the substrate. The pushing force control unit is configured to adjust a pushing force of the catalyst holding head by the pushing mechanism according to a position of the catalyst holding head or a contact area between the substrate and the catalyst when the catalyst projects to outside the substrate by the swing of the catalyst holding head.

[Configuration 2]

This application further discloses the following substrate processing apparatus as one embodiment. The pushing force control unit is configured to adjust the pushing force of the catalyst holding head by the pushing mechanism such that a pressure applied to a contact region between the substrate and the catalyst becomes constant.

[Configuration 3]

This application further discloses the following substrate processing apparatus as one embodiment. In a state where the catalyst projects to outside the substrate, the pushing force control unit is configured to decrease the pushing force of the catalyst holding head by the pushing mechanism as the position of the catalyst holding head is away from a center position of the substrate, and increase the pushing force of the catalyst holding head by the pushing mechanism as the position of the catalyst holding head approaches the center position of the substrate.

[Configuration 4]

This application further discloses the following substrate processing apparatus as one embodiment. The pushing force control unit is configured to decrease the pushing force of the catalyst holding head by the pushing mechanism as the contact area between the substrate and the catalyst decreases. The pushing force control unit is configured to increase the pushing force of the catalyst holding head by the pushing mechanism as the contact area between the substrate and the catalyst increases.

[Configuration 5]This application further discloses the following substrate processing apparatus as one embodiment. The pushing mechanism includes an elevating mechanism configured to move up and down the catalyst holding head. The pushing force control unit is configured to control moving up and down of the catalyst holding head by the elevating mechanism to adjust the pushing force.

[Configuration 6]

This application further discloses the following substrate processing apparatus as one embodiment. The catalyst holding head includes an elastic member and a base material. The elastic member holds the catalyst. The base material holds the elastic member. The pushing mechanism includes a fluid source. The fluid source supplies a fluid to a space formed between the base material and the elastic member. The pushing force control unit is configured to control a flow rate of the fluid supplied from the fluid source to the space to adjust the pushing force.

[Configuration 7]

This application further discloses the following substrate processing apparatus as one embodiment. The swing mechanism includes a swing arm and a rotation shaft. The swing arm holds the catalyst holding head. The rotation shaft rotatably holds the swing arm. The pushing force control unit is configured to calculate the position of the catalyst holding head based on a rotation angle of the swing arm.

[Configuration 8]

This application further discloses the following substrate processing apparatus as one embodiment. The pushing force control unit is configured to calculate the contact area between the substrate and the catalyst based on the position of the catalyst holding head and a diameter of the catalyst.

[Configuration 9]

This application further discloses a substrate processing method as one embodiment that includes: an installing step of installing a substrate to a stage with a surface to be processed upward; a pushing step of pushing a catalyst holding head that holds a catalyst to process the surface to be processed of the substrate against the surface to be processed of the substrate; a swinging step of swinging the catalyst holding head in a radial direction of the substrate; and an adjusting step of adjusting a pushing force of the catalyst holding head by the pushing mechanism according to a position of the catalyst holding head or a contact area between the substrate and the catalyst when the catalyst projects to outside the substrate by the swinging step.

[Configuration 10]

This application further discloses a substrate processing system as one embodiment that includes a conveyance mechanism, the substrate processing apparatus according to any one of the configurations 1 to 8 described above, a cleaning module, and a drying module. The conveyance mechanism conveys a substrate. The substrate processing apparatus is configured to process the substrate. The cleaning module is configured to clean the substrate processed by the substrate processing apparatus. The drying module is configured to dry the substrate cleaned by the cleaning module.

From the above-described embodiments, at least the following technical ideas are obtained.

[Configuration 11]

According to the configuration 11, a substrate processing apparatus is provided. In the substrate processing apparatus, a substrate as a process target is formed in an order of an insulating film layer in which a groove is formed, a barrier metal layer, and a wiring metal layer from below in at least a part of a region. The substrate processing apparatus includes a table that holds the substrate and a head that holds a catalyst. The catalyst contains a base metal.

[Configuration 12]

According to the configuration 12, in the substrate processing apparatus in the configuration 11, the catalyst is a single metal containing one or an alloy mainly containing one selected from the group consisting of titanium (Ti), chrome (Cr), molybdenum (Mo), tungsten (W), nickel (Ni), vanadium (V), iron (Fe), cobalt (Co), copper (Cu), hafnium (Hf), and tantalum (Ta).

Configuration 131

According to the configuration 13, in the substrate processing apparatus in the configuration 12, the catalyst is an alloy mainly containing one selected from the group consisting of titanium (Ti), chrome (Cr), molybdenum (Mo), tungsten (W), nickel (Ni), vanadium (V), iron (Fe), cobalt (Co), copper (Cu), hafnium (Hf), and tantalum (Ta). The alloy further contains at least one selected from the group consisting of ruthenium (Ru), rhodium (Rh), palladium (Pd), argentum (Ag), iridium (Ir), platinum (Pt), and aurum (Au).

[Configuration 14]

According to the configuration 14, in the substrate processing apparatus according to any one of the configurations from the configuration 11 to the configuration 13, the head holds a plurality of different kinds of catalysts.

[Configuration 15]

According to the configuration 15, the substrate processing apparatus according to any one of the configurations from the configuration 11 to the configuration 14 includes a nozzle that supplies a process liquid on the substrate held to the table.

[Configuration 16]

According to the configuration 16, in the substrate processing apparatus according to the configuration 15, the process liquid contains a liquid containing a compound having an oxidizing property, and an electrolyte.

[Configuration 17]

According to the configuration 17, in the substrate processing apparatus according to the configuration 16, the electrolyte contains at least one of hydrochloric acid, nitric acid, sulfuric acid, phosphoric acid, citric acid, oxalic acid, formic acid, acetic acid, potassium hydroxide, sodium hydroxide, calcium hydroxide, ammonia, potassium chloride, sodium chloride, and sodium sulfate.

[Configuration 18]

According to the configuration 18, in the substrate processing apparatus according to any one of the configurations from the configuration 11 to the configuration 17, the barrier metal layer and the wiring metal layer contain at least one of ruthenium (Ru), cobalt (Co), copper (Cu), molybdenum (Mo), tantalum (Ta), and titanium nitride (TiN).

[Configuration 19]

According to the configuration 19, in the substrate processing apparatus according to any one of the configurations from the configuration 11 to the configuration 18, the catalyst is held to the head by any one of methods of a sputtering method, a chemical vapor deposition method (CVD), a vapor deposition method, and a plating method.

### REFERENCE SIGNS LIST

10 . . . substrate processing apparatus
20 . . . stage
21 . . . wall member
30 . . . catalyst holding head
30-40 . . . process liquid supply passage
30-42 . . . supply port
30-49 . . . catalyst electrode
30-50 . . . counter electrode
31 . . . catalyst
32 . . . elastic member
33 . . . pressure chamber
34 . . . base material
35 . . . fluid source
40 . . . process liquid supply member
50 . . . swing arm
50-1 . . . shaft
50-2 . . . cover
50-4 . . . ball spline
50-6 . . . slip ring
50-8 . . . rotary joint
50-10 . . . rotation motor
50-12 . . . elevating air cylinder
50-14 . . . load cell
50-15 . . . PID controller
50-16a . . . first pipe line
50-16b . . . second pipe line
50-18a . . . electropneumatic regulator
50-18b . . . precise regulator
50-20a, 50-20b . . . solenoid valve
50-22a, 50-22b . . . pressure gauge
51 . . . rotation shaft
52 . . . pushing mechanism
53 . . . elevating mechanism
55 . . . swing mechanism
60 . . . conditioning member
61 . . . scrub cleaning member
90 . . . control unit
91 . . . pushing force control unit
100 . . . CARE module
101 . . . installing step
102 . . . supplying step
103 . . . pushing step
104 . . . relative movement step
105 . . . swinging step
106 . . . moving distance calculating step
107 . . . contact area calculating step
108, 110 . . . determining step
109 . . . adjusting step
200 . . . cleaning module
300 . . . film formation chamber
400 . . . robot
500 . . . load port
600 . . . drying module
1000 . . . substrate processing system
2-10 . . . substrate processing apparatus
2-20 . . . table
2-21 . . . wall
2-22 . . . electrode
2-25 . . . power source
2-30 . . . head
2-31 . . . catalyst
2-32 . . . base member
2-40 . . . nozzle
2-50 . . . arm
2-60 . . . conditioner
2-90 . . . control device
WF . . . substrate

What is claimed is:

1. A substrate processing apparatus comprising:
a stage for holding a substrate with a surface to be processed upward;
a catalyst holding head for holding a catalyst to process the surface to be processed of the substrate;
a pushing mechanism for pushing the catalyst holding head against the surface to be processed of the substrate;
a swing mechanism for swinging the catalyst holding head in a radial direction of the substrate; and
a pushing force control unit configured to adjust a pushing force of the catalyst holding head by the pushing mechanism according to a position of the catalyst holding head or a contact area between the substrate and the catalyst when the catalyst projects to outside the substrate by the swing of the catalyst holding head.

2. The substrate processing apparatus according to claim 1, wherein
the pushing force control unit is configured to adjust the pushing force of the catalyst holding head by the pushing mechanism such that a pressure applied to a contact region between the substrate and the catalyst becomes constant.

3. The substrate processing apparatus according to claim 1, wherein
in a state where the catalyst projects to outside the substrate, the pushing force control unit is configured to decrease the pushing force of the catalyst holding head by the pushing mechanism as the position of the catalyst holding head is away from a center position of the substrate, and increase the pushing force of the catalyst holding head by the pushing mechanism as the position of the catalyst holding head approaches the center position of the substrate.

4. The substrate processing apparatus according to claim 1, wherein
the pushing force control unit is configured to decrease the pushing force of the catalyst holding head by the pushing mechanism as the contact area between the substrate and the catalyst decreases, and the pushing force control unit is configured to increase the pushing force of the catalyst holding head by the pushing mechanism as the contact area between the substrate and the catalyst increases.

5. The substrate processing apparatus according to claim 1, wherein
the pushing mechanism includes an elevating mechanism configured to move up and down the catalyst holding head, and
the pushing force control unit is configured to control moving up and down of the catalyst holding head by the elevating mechanism to adjust the pushing force.

6. The substrate processing apparatus according to claim 1, wherein
the catalyst holding head includes an elastic member and a base material, the elastic member holds the catalyst, and the base material holds the elastic member,
the pushing mechanism includes a fluid source, and the fluid source is configured to supply a fluid to a space formed between the base material and the elastic member, and
the pushing force control unit is configured to control a flow rate of the fluid supplied from the fluid source to the space to adjust the pushing force.

7. The substrate processing apparatus according to claim 1, wherein
the swing mechanism includes a swing arm and a rotation shaft, the swing arm holds the catalyst holding head, and the rotation shaft rotatably holds the swing arm, and
the pushing force control unit is configured to calculate the position of the catalyst holding head based on a rotation angle of the swing arm.

8. The substrate processing apparatus according to claim 7, wherein
the pushing force control unit is configured to calculate the contact area between the substrate and the catalyst based on the position of the catalyst holding head and a diameter of the catalyst.

9. A substrate processing method comprising:
an installing step of installing a substrate to a stage with a surface to be processed upward;
a pushing step of pushing a catalyst holding head that holds a catalyst to process the surface to be processed of the substrate against the surface to be processed of the substrate;
a swinging step of swinging the catalyst holding head in a radial direction of the substrate; and
an adjusting step of adjusting a pushing force of the catalyst holding head by the pushing mechanism according to a position of the catalyst holding head or a contact area between the substrate and the catalyst when the catalyst projects to outside the substrate by the swinging step.

10. A substrate processing system comprising:
a conveyance mechanism for conveying a substrate;
the substrate processing apparatus configured to process the substrate according to claim 1;
a cleaning module configured to clean the substrate processed by the substrate processing apparatus; and
a drying module configured to dry the substrate cleaned by the cleaning module.

11. A substrate processing apparatus, wherein
a substrate as a process target is formed in an order of an insulating film layer in which a groove is formed, a barrier metal layer, and a wiring metal layer from below in at least a part of a region,
the substrate processing apparatus includes:
a table for holding the substrate; and
a head for holding a catalyst, and
the catalyst contains a base metal.

12. The substrate processing apparatus according to claim 11, wherein
the catalyst is a single metal containing one or an alloy mainly containing one selected from the group consisting of titanium (Ti), chrome (Cr), molybdenum (Mo), tungsten (W), nickel (Ni), vanadium (V), iron (Fe), cobalt (Co), copper (Cu), hafnium (Hf), and tantalum (Ta).

13. The substrate processing apparatus according to claim 12, wherein
the catalyst is an alloy mainly containing one selected from the group consisting of titanium (Ti), chrome (Cr), molybdenum (Mo), tungsten (W), nickel (Ni), vanadium (V), iron (Fe), cobalt (Co), copper (Cu), hafnium (Hf), and tantalum (Ta), and
the alloy further contains at least one selected from the group consisting of ruthenium (Ru), rhodium (Rh), palladium (Pd), argentum (Ag), iridium (Ir), platinum (Pt), and aurum (Au).

14. The substrate processing apparatus according to claim 11, wherein
the head holds a plurality of different kinds of catalysts.

15. The substrate processing apparatus according to claim 11, comprising
a nozzle for supplying a process liquid on the substrate held to the table.

16. The substrate processing apparatus according to claim 15, wherein
the process liquid contains a liquid containing a compound having an oxidizing property, and an electrolyte.

17. The substrate processing apparatus according to claim 16, wherein
the electrolyte contains at least one of hydrochloric acid, nitric acid, sulfuric acid, phosphoric acid, citric acid, oxalic acid, formic acid, acetic acid, potassium hydroxide, sodium hydroxide, calcium hydroxide, ammonia, potassium chloride, sodium chloride, and sodium sulfate.

18. The substrate processing apparatus according to claim 11, wherein
the barrier metal layer and the wiring metal layer contain at least one of ruthenium (Ru), cobalt (Co), copper (Cu), molybdenum (Mo), tantalum (Ta), and titanium nitride (TiN).

19. The substrate processing apparatus according to claim 11, wherein
the catalyst is held to the head by any one of methods of a sputtering method, a chemical vapor deposition method (CVD), a vapor deposition method, and a plating method.
